(19) United States
(12) Patent Application Publication
(10) Pub. No.: US 2017/0201253 A1
(43) Pub. Date: Jul. 13, 2017

(54) PLANAR SWITCH AND PLANAR SWITCH UNIT

(71) Applicant: MINEBEA CO., LTD., KITASAKU-GUN (JP)

(72) Inventors: Kiyoshi OMORI, TOKYO (JP); Yasutoshi OBATA, YOKOHAMA-SHI (JP)

(21) Appl. No.: 15/398,461

(22) Filed: Jan. 4, 2017

(30) Foreign Application Priority Data
Jan. 8, 2016 (JP) 2016-002161

(51) Int. Cl. H03K 17/96

(52) U.S. Cl. CPC H03K 17/962; H03K 2217/96079

(57) ABSTRACT

A planar switch that is attached to a switch attachment member provided inside an opening and embedded in the opening, includes: a switch device, at least a part of which is supported to the switch attachment member and a sensor face of which is disposed to face a side of the opening; a urging member, which is disposed between the switch attachment member and the switch device and urges the switch device toward the opening; and a distance adjusting member, which adjusts a distance between the switch device and the switch attachment member while being urged by the urging member.

### CROSS-REFERENCE TO RELATED APPLICATION

This application claims priority from Japanese Patent Application No 2016-002161 filed on Jan. 8, 2016, the entire subject matter of which is incorporated herein by reference.

### TECHNICAL FIELD

This disclosure relates to a planar switch and a planar switch unit.

### BACKGROUND

A lighting switch in JP-A-2012-059580 can be used in a state of being attached and embedded in a wall and is also used as a remote controller unit when being detached from the wall.

In the lighting switch disclosed in JP-A-2012-059580, the switch is configured by an electrostatic capacitance sensor, and thus is formed flat in a switch device.

### SUMMARY

In a case where the switch is configured by the electrostatic capacitance sensor disclosed in JP-A-2012-059580, the switch surface can be made flat.

Therefore, for example, when the switch surface can be made to become flush with the wall (for example, the switch surface and the wall surface form a flat plane) in a case where the switch is installed in a wall of a building, the switch surface does not protrude, and thus the appearance of a room can be improved.

However, a distance dimension between the inner wall and the outer wall of buildings varies depending on buildings. Therefore, even when the switch surface becomes flat, it cannot be said that the switch surface always becomes flush with the outer wall when the switch is attached to the inner wall.

In this way, when the switch surface is installed not to protrude from the outer wall, there is a problem in that the installation is not simply performed even if the switch surface becomes flat. Therefore, there is a request for a switch which has a high flexibility in installation of the switch and thus, for example, can simply realize the installation state of the switch in which the switch surface and the opening become flush with each other.

This disclosure is to provide a planar switch which is embedded in the opening, and has a high flexibility in installation.

According to this disclosure, a planar switch that is attached to a switch attachment member provided inside an opening and embedded in the opening, comprising: a switch device, at least a part of which is supported to the switch attachment member and a sensor face of which is disposed to face a side of the opening; a urging member, which is disposed between the switch attachment member and the switch device and urges the switch device toward the opening; and a distance adjusting member, which adjusts a distance between the switch device and the switch attachment member while being urged by the urging member.

According to this disclosure, a planar switch unit includes a planar switch described above; and a switch attachment member.

According to this disclosure, it is possible to provide an embedded type of a planar switch which is embedded in an opening and has a high flexibility in installation.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a perspective view illustrating a state in which a planar switch of an embodiment of this disclosure is embedded in a wall surface of a room;

FIG. 2 is a perspective view of the planar switch unit of the embodiment of this disclosure;

FIG. 3 is an exploded perspective view illustrating only a switch device of the embodiment;

FIG. 4 is an exploded perspective view of a controller unit of the embodiment;

FIG. 5 is a perspective view illustrating a state in which the controller unit of the embodiment is partially assembled;

FIG. 6 is an exploded perspective view of a sensor unit of the embodiment;

FIGS. 7A and 7B are cross-sectional views illustrating a configuration of an electrostatic capacitive sensor potion of the embodiment, in which FIG. 7A is a diagram illustrating a state in which the switch is not operated, and FIG. 7B is a diagram illustrating a state in which the switch is operated;

FIG. 8 is an exploded perspective view of the planar switch unit in which the switch device of the embodiment is omitted;

FIG. 9 is a perspective view illustrating a state in which urging members are attached to a switch attachment member of the embodiment; and

FIG. 10 is a diagram illustrating a method of adjusting a distance from the switch attachment member of the switch device of the embodiment using a distance adjusting member.

### DETAILED DESCRIPTION

Hereinafter, aspects (hereinafter, referred to as “embodiments”) for carrying out this disclosure will be described in detail with reference to the accompanying drawings.

The same elements will be attached with the same symbol the entire explanation of the embodiments.

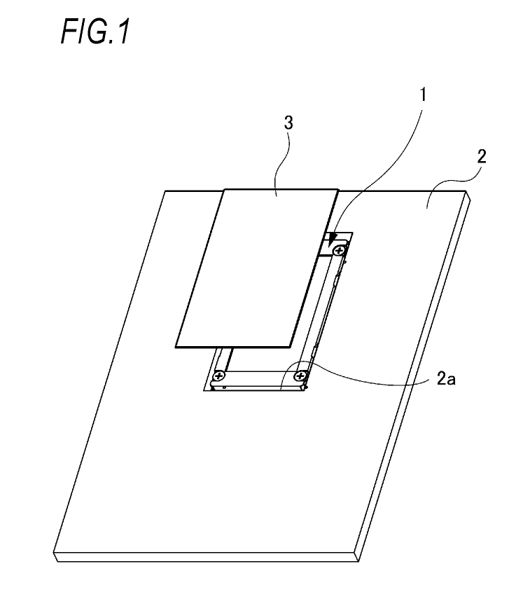

FIG. 1 is a perspective view illustrating a state in which a planar switch 1 of the embodiment according to this disclosure is embedded in a wall surface of a room.

The planar switch 1 of this embodiment serves as a switch of a lighting apparatus of a room, for example.

However, the planar switch 1 of this disclosure may be used as a switch for operating apparatuses (air conditioning systems, home appliances, shutters, and curtains) other than the lighting apparatus.

As illustrated in FIG. 1, an opening 2a is formed in an outer wall 2 of a room. The planar switch 1 is provided inside the opening 2a. A lid 3 is provided to become flush with the outer wall 2 so as to seal the opening 2a. A wall paper (not illustrated) is provided with an opening in a portion corresponding to the lid 3 or a transparent or translucent portion corresponding to the lid 3.

The lid 3 is attached to the outer wall 2, and is disposed close or coming into contact with the planar switch 1 so that the lid 3 is not bent even when pressed.

Additionally, the wall paper is formed with a drawing pattern in a portion corresponding to the lid 3, or may be made translucent.

Herein, in a case where the lid 3 is made by a half mirror and the planar switch 1 does not illuminate, the surface of the lid 3 is visibly recognized as a mirror surface, and thus the planar switch 1 is hardly recognized. Therefore, the planar switch goes with the interior of the room. In a case where the planar switch 1 is illuminated, if a picture or a symbol serving as the operation portion of the switch is printed in the half mirror, the printed pattern is appeared, and thus a novel and beautiful appearance can be realized.

Otherwise, the lid 3 may be made by printing a picture or a symbol serving as the operation portion of the switch in the transparent plate, or a film with a picture or a symbol serving as the operation portion of the switch may be provided in the lower surface of the lid 3.

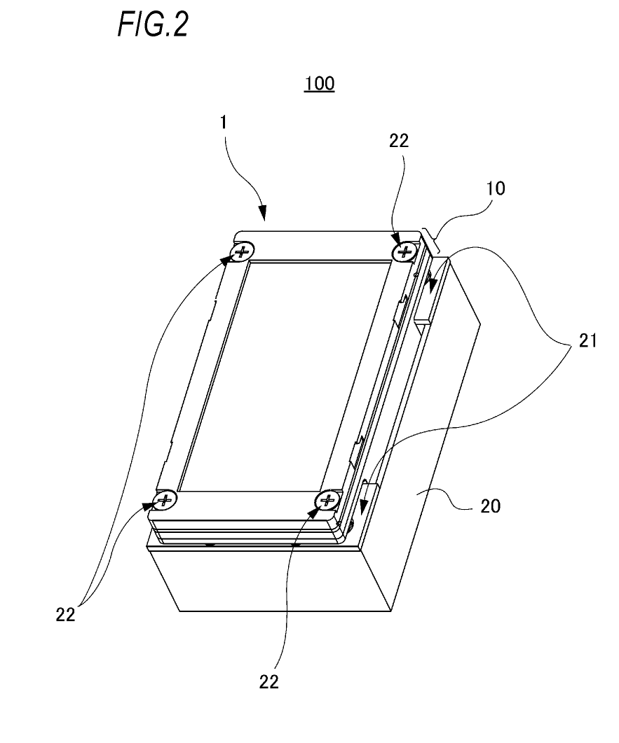

FIG. 2 is a perspective view illustrating a planar switch unit 100 which is provided with the planar switch 1 and a switch attachment member 20.

As illustrated in FIG. 2, the planar switch 1 is provided with a switch device 10 which is disposed on a side of the opening 2a (see FIG. 1) toward a sensor face, a urging member 21 which is attached to the switch attachment member 20 and urges the switch device 10 toward the opening 2a, and a distance adjusting member 22 which adjusts a distance from the switch attachment member 20 of the switch device 10 against a urging force of the urging member 21. At least a part of the switch device 10 is supported to the switch attachment member 20 through the urging member 21 which is disposed between the switch attachment member 20 and the switch device 10.

Hereinafter, the description will be made about the configurations of the switch device 10, the switch attachment member 20, the urging member 21, and the distance adjusting member 22.

(Configuration of Switch Device)

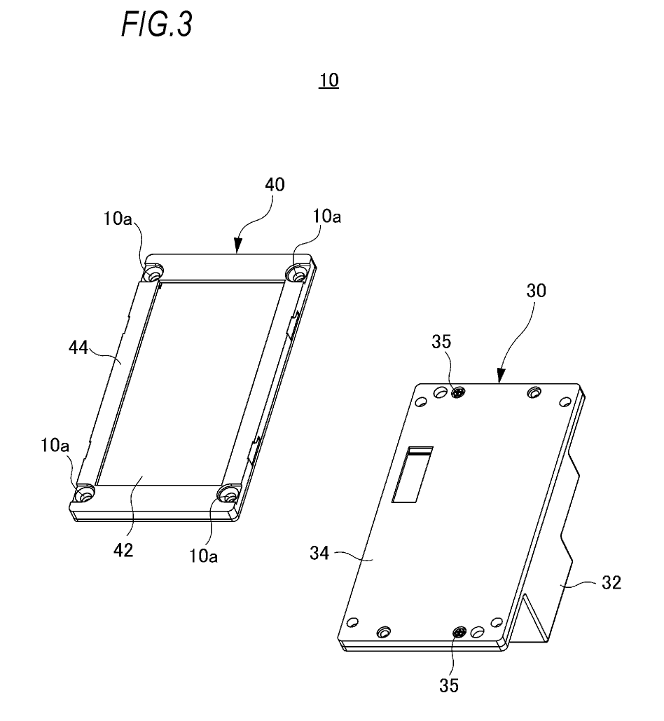

FIG. 3 is an exploded perspective view of the switch device 10.

As illustrated in FIG. 3, the switch device 10 is provided with a controller unit 30 which is disposed on a side of the switch attachment member 20 (see FIG. 2), and a sensor unit 40 which is attached to the controller unit 30 such that the sensor face to be described is positioned toward the opening 2a (see FIG. 1).

(Controller Unit)

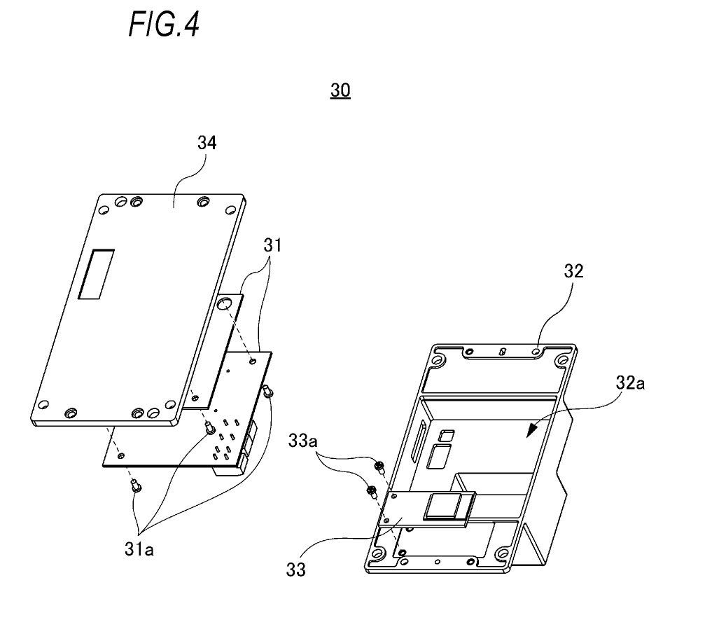

FIG. 4 is an exploded perspective view of the controller unit 30.

As illustrated in FIG. 4, the controller unit 30 is provided with two controller substrates 31 which control the switch device 10, a controller case 32 which includes a controller substrate accommodating recess 32a where the controller substrates 31 are accommodated, a radio module 33 which is attached to the controller case 32, and a cover 34 which is attached to the controller case 32 to cover the radio module 33 and the controller substrate 31.

The controller substrate 31 is a substrate in which a circuit for a general control of the switch device 10.

The radio module 33 is used, for example, to wirelessly transmit a content of a user operating the switch device 10 to the lighting apparatus which is a target of the switch device 10.

In this embodiment, the controller substrate 31 is attached to the cover 34 by a screw 31a, and the radio module 33 is attached to the controller case 32 by a screw 33a.

The controller substrate 31 is connected by an electric wire (not illustrated) which is detachably attached to the sensor unit 40 and the radio module 33.

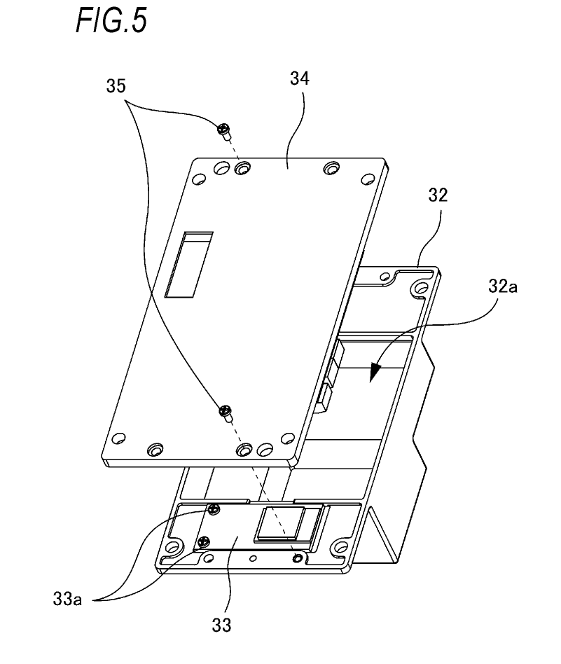

FIG. 5 is a perspective view illustrating a partially assembled state in which the controller substrate 31 is attached to the cover 34 and the radio module 33 is attached to the controller case 32.

As described above, after the controller substrate 31 is attached to the cover 34 and the radio module 33 is attached to the controller case 32, the cover 34 is attached to the controller case 32 by a screw 35.

In this way, when the cover 34 is attached, it comes to the state of the controller unit 30 illustrated in FIG. 3, that is, a state in which the radio module 33 and the controller substrate 31 are covered by the cover 34 and accommodated in the controller case 32.

(Sensor Unit)

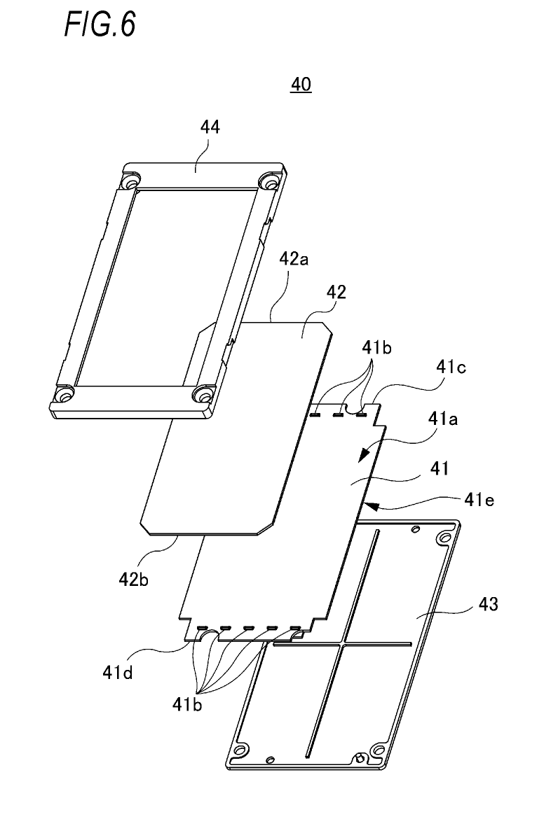

FIG. 6 is an exploded perspective view of the sensor unit 40.

As illustrated in FIG. 6, the sensor unit 40 is provided with a sensor substrate 41 in which a plurality of LEDs 41b are provided in a surface 41a toward the opening 2a (see FIG. 1), and a light guiding plate 42 which is disposed in the surface 41a of the sensor substrate 41 in a state where its side surface faces a light emitting surface of the LED 41b.

Specifically, five LEDs 41b are respectively disposed on a side of one end 41c of the sensor substrate 41 and on a side of the other end 41d, which faces the one end 41c, so as to be in parallel along with the one end 41c and the other end 41d. An electrostatic capacitive sensor portion is provided between the LEDs 41b provided at the both ends.

In other words, the surface 41a of the sensor substrate 41 serves as the sensor face, and the surface 41a of the sensor face arranged to be directed to the opening 2a (see FIG. 1). Therefore, the LED 41b is provided in the surface 41a to be directed to the opening 2a of the sensor substrate 41 (see FIG. 1).

Hereinafter, although the electrostatic capacitive sensor portion may have a general configuration, the electrostatic capacitive sensor portion of this embodiment is configured as follows.

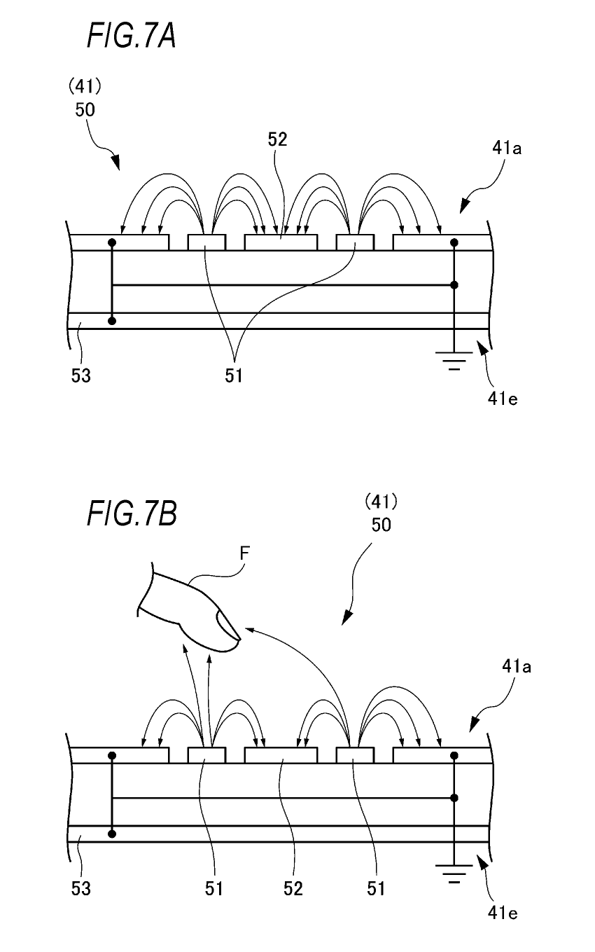

FIGS. 7A and 7B are diagrams illustrating the configurations of the electrostatic capacitive sensor portion of this embodiment, which illustrate a cross-sectional view of the sensor substrate 41 where an electrostatic capacitive sensor portion 50 of the sensor substrate 41 is located.

As illustrated in FIG. 7A, the electrostatic capacitive sensor portion 50 of the sensor substrate 41 is provided with a drive line 51 and a sensor line 52 which are positioned on the surface 41a of the sensor substrate 41, and a ground 53 which is positioned on a rear surface 42e of the sensor substrate 41.

Electrical fields are generated between the drive line 51, the sensor line 52, and the ground 53. In FIGS. 7A and 7B, the electric fields are illustrated by arrows showing electric flux lines.

In this state, as illustrated in FIG. 7B, when a human finger F approaches, the electric flux lines are attracted toward the finger F, and the number of electric flux lines toward the sensor line 52 is reduced.

When the reduction of the electric flux lines (that is, a variation in electrostatic capacity) is detected, it is detected whether the switch is operated.

The electrostatic capacitive sensor portion 50 may have other general configurations. In the case of the configuration for detecting a variation in the electric flux lines of this embodiment, the operation of the switch can be detected by merely the approaching of the finger F even when the finger F is separated from the sensor face (the surface 41a).

Therefore, even in a case where the light guiding plate 42 and the lid 3 (see FIG. 1) are provided on the sensor face (the surface 41a), it is possible to preferably detect whether the switch is operated.

It is possible to detect the approaching of the finger F even in a case where there is a gap (air layer) between the sensor face (the surface 41a) and the light guiding plate 42 and between the light guiding plate 42 and the lid 3.

Therefore, there is no problem even when a gap is present from the sensor face (the surface 41a) to the lid 3, thereby a strict dimension management and high assembly accuracy will be not necessary for the respective members.

Returning to FIG. 6, a side surface of one end 42a of the light guiding plate 42 faces the light emitting surface of the LED 41b provided on a side of the one end 41c of the sensor substrate 41, and a side surface of the other end 42b facing the one end 42a of the light guiding plate 42 to face the light emitting surface of the LED 41b provided on a side of the other end 41d of the sensor substrate 41. Thus, the light guiding plate 42 is disposed at a position between the LED 41b provided on a side of the one end 41c of the sensor substrate 41 and the LED 41b provided on a side of the other end 41d of the sensor substrate 41.

The sensor unit 40 is provided with a sensor case 43, which is disposed on a side of a rear surface 41e on a side opposite to the surface 41a of the sensor substrate 41 and accommodates the sensor substrate 41 and the light guiding plate 42, and a cover reflector 44, which is attached to the sensor case 43, presses an outer peripheral surface of the light guiding plate 42 toward the sensor case 43, and reflects a leakage light from the side surface of the light guiding plate 42 toward the light guiding plate 42.

It is preferable that the cover reflector 44 has high reflectance in order that the light is reflected toward the light guiding plate 42 and the leaking light is returned to the light guiding plate 42 and. Therefore, the cover reflector may be made of a white resin.

The sensor case 43 and the cover reflector 44 may be pressed fit into one, for example, may be integrated using an engaging structure, or may be integrated using a locking structure of a locking claw. However, an integration method is not particularly limited.

The light guiding plate 42 is provided on the sensor substrate 41, and these are accommodated in the sensor case 43. In a state where the cover reflector 44 is integrated with the sensor case 43 to press the outer peripheral surface of the light guiding plate 42, the sensor unit 40 becomes a state where the surface being directed to the opening 2a (see FIG. 1) illustrated in FIG. 3 comes to be almost flat.

Herein, when the lid 3 is made by the half mirror for example as described in the introduction section, the surface of the lid 3 is visibly recognized as a mirror surface in a case where the planar switch 1 does not illuminate.

In a case where a picture or a symbol serving as the operation portion of the switch is printed in the half mirror, and the printed portion is appeared, the position of the switch can be recognized when the planar switch 1 illuminates.

Otherwise, the lid 3 may be made by printing a picture or a symbol serving as the operation portion of the switch in the transparent plate, or a film printed with a picture or a symbol serving as the operation portion of the switch may be provided in the lower surface of the lid 3.

Meanwhile, the switch device 10 made of the controller unit 30 and the sensor unit 40 is desirably configured as the switch device 10 illustrated in FIG. 2 to detachably attach the sensor unit 40 using a configuration such as an engaging claw with respect to the controller unit 30 illustrated in FIG. 3.

In this way, when the sensor unit 40 is detachably attached to the controller unit 30, the portion of the sensor unit 40 is only changed to the sensor unit 40 according to the design even in a case where the planar switch 1 is changed in design. The controller unit 30 itself can be used in common by the respective sensor units 40.

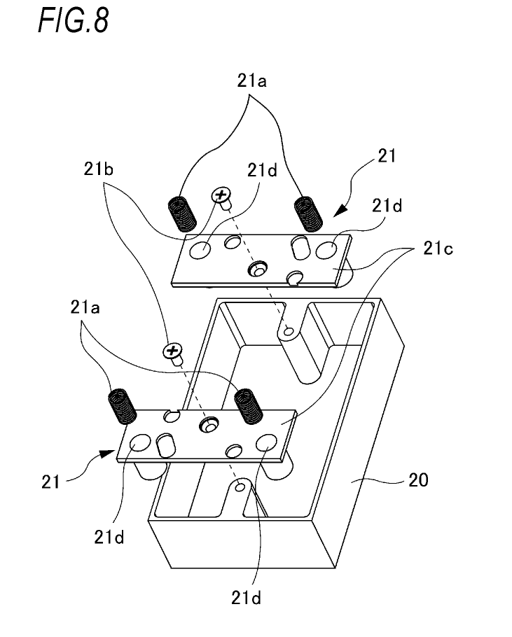

Next, the configurations of the switch attachment member 20, the urging member 21, and the distance adjusting member 22 will be described with reference to FIGS. 8 to 10 which are exploded perspective views of the planar switch 1 from which the switch device 10 is omitted.

(Configuration of Switch Attachment Member)

As illustrated in FIG. 8, a JIS-standard switch box which commercially comes into a market is used as the switch attachment member 20.

With such a configuration, the switch attachment member 20 can be installed inside the opening 2a (see FIG. 1) according to a procedure of installing a normal switch box.

In a case where the switch is already installed in a wall, the planar switch 1 can be installed such that the existing switch is removed and the already installed switch box is used without replacing.

The switch attachment member 20 is not limited to a commodity switch box, and the switch attachment member 20 may be made differently from the commodity switch box as needed.

(Urging Member)

As illustrated in FIG. 8, the urging member 21 is provided with an elastic body 21a, which is made of four compression coil springs to urge the switch device 10 (not illustrated), and two fixing plates 21c, which support the elastic body 21a and are attached to the switch attachment member 20 by screws 21b.

In each of the fixing plates 21c, there are provided two spring receiving recesses 21d which receive a part of the compression coil spring to arrange the elastic body 21a made of the compression coil spring at a position corresponding to a corner of the switch device 10.

As to be described below, a screw fastening portion (not illustrated) is formed in the bottom surface of the spring receiving recess 21d to engage the screw (not illustrated).

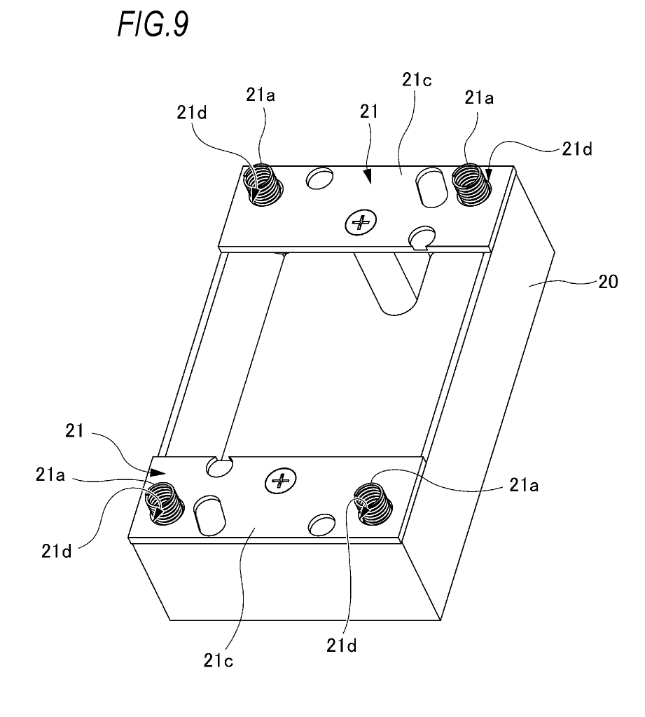

FIG. 9 is a perspective view illustrating a state in which the urging member 21 is attached to the switch attachment member 20.

As illustrated in FIG. 9, the fixing plates 21c are attached to one end of the switch attachment member 20 and the other end facing the one end. A part of the elastic body 21a is received in the spring receiving recess 21d such that elastic body 21a is positioned at the corner of the switch attachment member 20.

The remaining portion of the elastic body 21a, which is not received in the spring receiving recess 21d, protrudes from the spring receiving recess 21d.

Herein, as can be seen from FIG. 2, the switch device 10 has almost the same outline as that of the switch attachment member 20. As illustrated in FIG. 9, the elastic body 21a disposed at the corner of the switch attachment member 20 urges the corner of the switch device 10.

In this way, the switch device 10 is urged with being supported at four points, and thus a high posture stability can be obtained.

In this example, two fixing plates 21c are used. However, both ends of the fixing plates 21c may be connected to form a frame shape, so that the fixing plates 21c become one body.

The fixing plate 21c may be provided for respective elastic bodies 21a.

Therefore, the fixing plate 21c is not necessary to be two, but one or more fixing plates 21c may be provided.

Furthermore, the number of elastic bodies 21a is to be equal to the sum of the spring receiving recesses 21d provided in all the fixing plates 21c. However, the number of spring receiving recesses 21d provided in the one fixing plate 21c is changed depending on the number of fixing plates 21c.

In other words, in a case where the fixing plates 21c are provided in correspondence with the respective elastic bodies 21a, one spring receiving recess 21d is provided in respective fixing plates 21c. In a case where one fixing plate 21c is provided with respect to two elastic bodies 21a as in this embodiment, two spring receiving recesses 21d are provided in respective fixing plates 21c.

Therefore, the fixing plate 21c is not necessarily provided with two spring receiving recesses 21d. One or more spring receiving recesses 21d are provided according to its type.

In this embodiment, the elastic bodies 21a are configured by four compression coil springs, but also the number of elastic bodies 21a is not limited to four as long as the switch device 10 can be urged to take a stable posture.

For example, the switch device 10 can be urged in a stable posture even when the switch device 10 is urged by being supported at three points using the elastic bodies 21a made of three compression coil springs.

On the other hand, the elastic body 21a is not limited to the compression coil spring, and may be made of a plate spring.

In such configuration, the switch device can be supported at two points by using one plate spring if the plate spring has a V shape, so that the switch device 10 can be urged to be supported in the four points using two plate springs similarly to this embodiment.

Therefore, in a case where the plate spring is used as the elastic body 21a, two or more (plural) elastic bodies 21a may be suitable.

(Distance Adjusting Member)

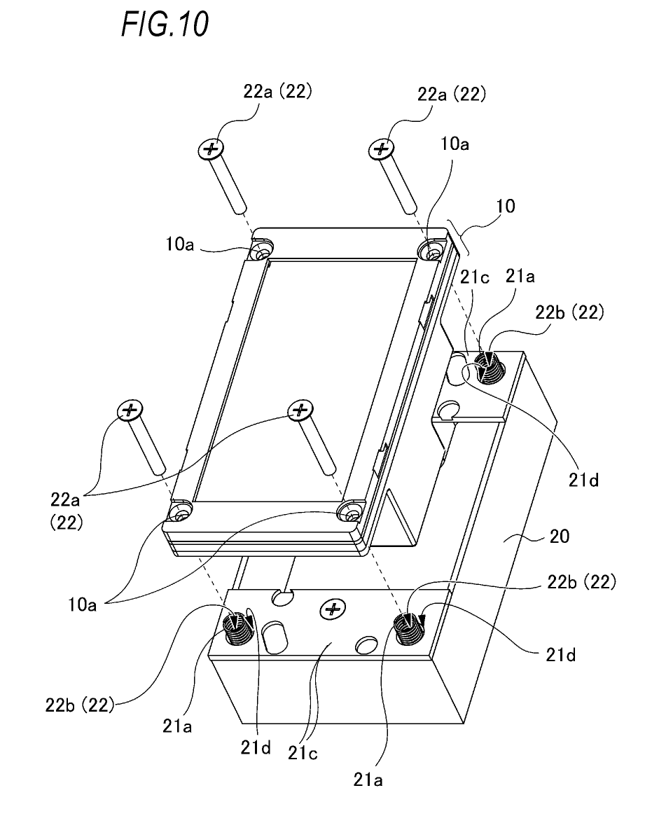

FIG. 10 is a diagram illustrating a method of adjusting a distance from the switch attachment member 20 of the switch device 10 by using the distance adjusting member 22.

As illustrated in FIG. 10, screw holes (holes) 10a through which screws 22a pass are provided at four corners in the switch device 10.

The screw hole 10a is formed to correspond to the position of the spring receiving recess 21d of the fixing plate 21c.

As described above, while not illustrated in the drawing, a screw fastening portion 22b to which the screw 22a is engaged is formed in the bottom surface of the spring receiving recess 21d of the fixing plate 21c.

Therefore, the screw 22a passes through the screw hole 10a of the switch device 10, and passes through the center of the elastic body 21a made of the compression coil spring, and then engaged to the screw fastening portion 22b. In such configuration, a separation distance from the switch attachment member 20 to the switch device 10 can be changed according to an amount of engagement to the screw fastening portion 22b of the screw 22a.

Meanwhile, the switch device 10 is urged in a direction away from the switch attachment member 20 by the elastic body 21a.

Therefore, the switch device 10 comes to be settled at a position away from the separation distance from the switch attachment member 20 determined by the screw 22a.

In this way, the distance adjusting member 22 is configured by the screw fastening portion 22b provided in the fixing plate 21c and the screw 22a engaged to the screw fastening portion 22b.

In this embodiment, the screw fastening portion 22b is formed in the bottom surface of the spring receiving recess 21d, but there is no need to be formed in the bottom surface of the spring receiving recess 21d, and may be formed at an appropriate position.

In this embodiment, the distance adjusting member 22 is configured by four screws 22a and four screw fastening portions 22b, but the configuration may be changed such that the number of screws 22a is set to three and the number of screw fastening portions 22b is also set to three accordingly.

According to the planar switch 1 configured as described above, the distance of the switch device 10 from the switch attachment member 20 can be adjusted only by adjusting the amount of engagement of the screw 22a using a screw driver or something, thereby causing the switch device 10 to be approached or separated with respect to the switch attachment member 20.

Therefore, it is possible to adjust the distance from the switch attachment member 20 installed inside the opening 2a (see FIG. 1) such that the switch device 10 is disposed at an appropriate position with respect to the opening 2a (see FIG. 1).

As described in this embodiment, when the screws 22a are provided in multiple places, an inclination of the switch device 10 with respect to the switch attachment member 20 can be adjusted by changing the amount of engagement of the respective screws 22a.

Therefore, even in a case where there is a need to adjust a inclination in order to set an end surface on a side of the opening 2a (see FIG. 1) of the switch device 10 to be flat with respect to the opening 2a (see FIG. 1), the inclination can be simply adjusted.

While having been described with reference to the embodiments, this disclosure is not limited to these embodiments. Various changes can be made within a scope of this disclosure.

In the above, the description has been made about a case where the planar switch 1 is mainly installed in a wall of a room. However, the installation place is not limited to a wall of a room, but may be furniture such as a desk or household electric appliances for example.

In the above, the description has been made about a case where the planar switch 1 is installed not to form a step in a portion of the opening 2a. However, since the planar switch 1 of this disclosure can be adjusted in its inclination, the planar switch may be installed in a place being tilted.

Furthermore, in a case where the distance between the planar switch 1 and the switch attachment member 20 is given in advance, a guide pin may be used in place of the screw 22a to fix the switch device by fitting or by adhesive. By using the guide pin, the distance is easily determined with accuracy. Accordingly, in a case where there are a number of planar switches 1, it is expected that the installation time can be reduced.

In this way, this disclosure is not limited to the specific embodiments, but includes various changes which can be clearly known by a person skilled in the art from the claims.

What is claimed is:

1. A planar switch that is attached to a switch attachment member provided inside an opening and embedded in the opening, comprising:
a switch device, at least a part of which is supported to the switch attachment member and a sensor face of which is disposed to face a side of the opening;
a urging member, which is disposed between the switch attachment member and the switch device and urges the switch device toward the opening; and
a distance adjusting member, which adjusts a distance between the switch device and the switch attachment member while being urged by the urging member.

2. The planar switch according to claim 1,
wherein a plurality of the distance adjusting members are provided, and
wherein each of the plurality of the distance adjusting members is adjustable individually.

3. The planar switch according to claim 1,
wherein the urging member includes
a plurality of elastic bodies, which urge the switch device, and
one or more fixing plates, which support the elastic body and are attached to the switch attachment member.

4. The planar switch according to claim 3,
wherein the distance adjusting member includes
a plurality of screws, which are engaged with one or more screw fastening portions provided in the fixing plate, and
wherein a plurality of holes through which the screw passes are provided in the switch device.

5. The planar switch according to claim 4,
wherein the elastic body is a compression coil spring,
wherein the fixing plate includes one or more spring receiving recesses which receive at least a part of the compression coil spring, and
wherein the screw fastening portions are provided in the spring receiving recesses.

6. The planar switch according to claim 1,
wherein the switch device includes:
a controller unit, which is disposed at a side of the switch attachment member; and
a sensor unit, which is attached to the controller unit such that the sensor faces the side of the opening.

7. The planar switch according to claim 6,
wherein the controller unit includes
a controller substrate, which controls the switch device,
a controller case, which includes a controller substrate accommodating recess to accommodate the controller substrate,
a radio module, which is attached to the controller case, and
a cover, which is attached to the controller case and covers the radio module and the controller substrate.

8. The planar switch according to claim 6,
wherein the sensor unit includes
a sensor substrate, on which an LED is provided to face the opening,
a light guiding plate, which is disposed such that a side surface of the light guiding plate faces a light emitting surface of the LED,
a sensor case, which is disposed at a rear side of the sensor substrate and accommodates the sensor substrate and the light guiding plate, and
a cover reflector, which is attached to the sensor case, presses an outer peripheral surface of the light guiding plate toward the sensor case, and reflects a leaking light from a side surface of the light guiding plate toward the t guiding plate.

9. The planar switch according to claim 6,
wherein the sensor unit is an electrostatic capacitive type.

10. A planar switch unit comprising:
the planar switch according to claim 1; and
the switch attachment member.
